(19) United States
(12) Patent Application Publication
(10) Pub. No.: US 2007/0285101 A1
(43) Pub. Date: Dec. 13, 2007

(54) EQUIPMENT MONITORING DEVICES

(76) Inventor: Daren L. Kissinger, Deale, MD (US)

Correspondence Address: Jay A. Stelacone, Esq.;Law Office of Thomas M. Isaacson, 10415 Southern Maryland Blvd., Dunkirk, MD, 20754, US

(21) Appl. No.: 11/422,956

(22) Filed: Jun. 8, 2006

(51) Int. Cl. G01R 31/08

(52) U.S. Cl. 324/522

(57) ABSTRACT

An equipment monitoring device for monitoring a heating, ventilation, and air conditioning (HVAC) system configured to control an internal environment of a structure may include a current transformer configured to sense current being supplied from a power source to a first component of the HVAC system and a gauge configured to display the amount of current being supplied from the power source to the first component based on the current sensed by the current transformer.

### TECHNICAL FIELD

The present invention is directed generally to equipment monitoring. More particularly, the present invention is directed to monitoring devices for commercial and residential heating, ventilation, and air conditioning (HVAC) systems.

### BACKGROUND

When monitoring the performance of conventional HVAC systems, a skilled technician is required to take apart the HVAC unit, leak refrigerant, and check the amps and volts being drawn by the various components of the HVAC system.

Some large conventional HVAC systems for commercial applications may be equipped with a built-in monitoring unit. These built-in units typically monitor larger systems having large water pipes that be easily adapted for sensing of temperature and/or pressure. Conventional built-in units can be equipped with digital controls and a controller/computer board for monitoring. These features can significantly increase the cost of the HVAC system. Such units are typically customized for a particular piece of equipment or for a particular client's needs, and cannot be used to retrofit previously existing systems.

It may be desirable to provide a relatively inexpensive monitoring device that can be used to monitor a variety of systems, including HVAC systems, where amps need to be sensed and monitored. It may be desirable to provide a monitoring device that can be retrofit to pre-existing systems.

### SUMMARY

According to various aspects of the disclosure, an equipment monitoring device for monitoring a heating, ventilation, and air conditioning (HVAC) system configured to control an internal environment of a structure may include a current transformer configured to sense current being supplied from a power source to a first component of the HVAC system and a gauge configured to display the amount of current being supplied from the power source to the first component based on the current sensed by the current transformer.

In accordance with some aspects of the disclosure, a method for monitoring a heating, ventilation, and air conditioning (HVAC) system configured to control an internal environment of a structure may comprise monitoring current being supplied from a power source to a first component of the HVAC system without drawing power from the system.

According to various aspects, an equipment monitoring device for monitoring a heating, ventilation, and air conditioning (HVAC) system configured to control an internal environment of a structure may comprise a first gauge configured to display current being drawn by a fan employed by the HVAC system, second gauge configured to display pressure of refrigerant being discharged from a pump employed by the HVAC system, third gauge configured to display pressure of refrigerant being drawn into the pump, and a fourth gauge configured to display current being drawn by the pump.

It is to be understood that both the foregoing general description and the following detailed description are exemplary and explanatory only and are not restrictive of the invention.

### BRIEF DESCRIPTION OF THE DRAWINGS

The accompanying drawings, which are incorporated in and constitute a part of this specification, illustrate several exemplary embodiments of the invention and, together with the description, serve to explain the principles of the invention. In the drawings,

FIG. 1 is a perspective view of an exemplary monitoring device in accordance with various aspects of the invention.

FIG. 2 is a perspective view of an exemplary monitoring device associated with an exemplary HVAC system in accordance with various aspects of the invention.

### DETAILED DESCRIPTION

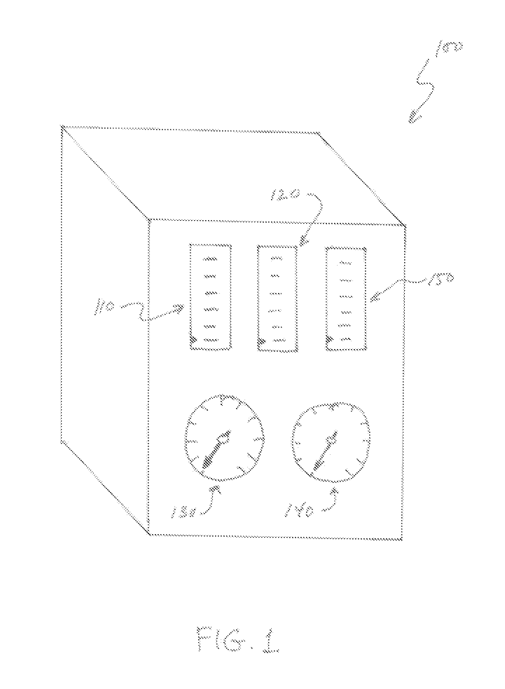

An exemplary embodiment of an monitoring device 100 is illustrated in FIG. 1. The monitoring device 100 may include a plurality of gauges 110, 120, 130, 140, 150. It should be appreciated that the device 100 may contain more or fewer than the five gauges illustrated in FIG. 1. The monitoring device 100 may be connected to an HVAC system in order to monitor various components of such a system, as will be described in more detail below.

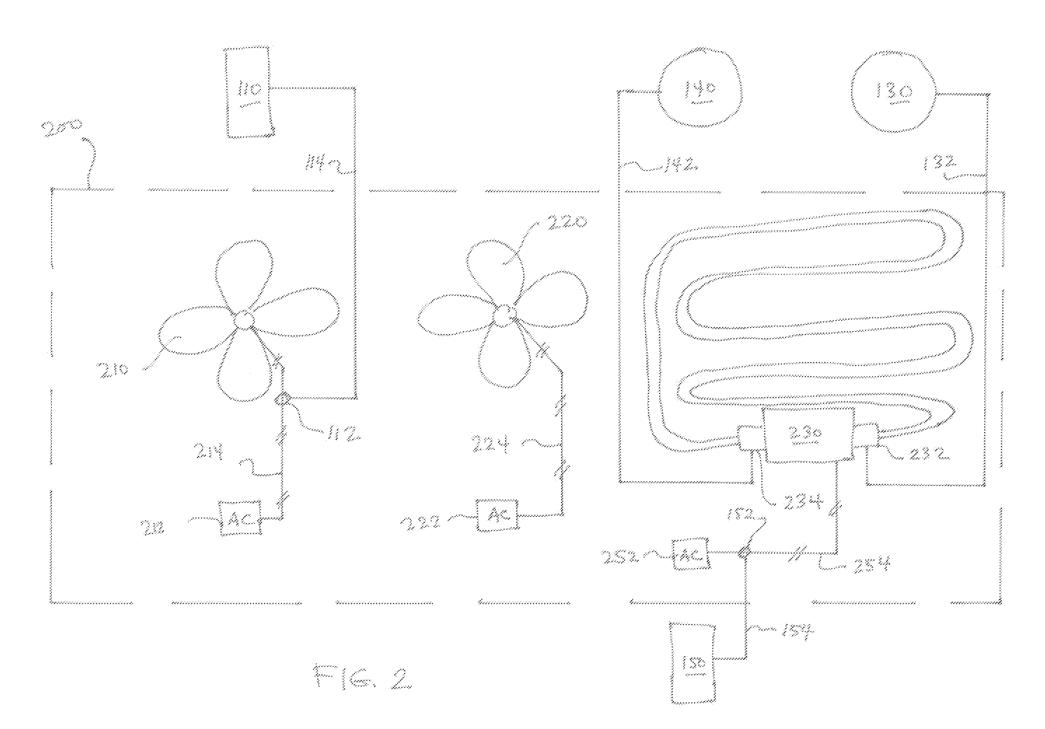

According to various aspects, the monitoring device 100 may be connected to a conventional HVAC system such as, for example, the HVAC system 200 illustrated in FIG. 2. The HVAC system 200 may be configured to provide heating, ventilation, and/or air conditioning to the interior of a structure (not shown).

The HVAC 200 system may include a first fan 210 disposed internal of the structure, a second fan 220 external to the structure, and a pump 230 configured to direct refrigerant to condenser coils 240 of the system. The first fan 210 may be powered by an alternating current (ac) power source 212 via electrical wire 214. Similarly, second fan 220 may be powered by an ac power source 222 via electrical wire 224.

The first gauge 110 of the monitoring device 100 may be configured to monitor the current being drawn by the first fan 210. The first gauge 110 may be, for example, an analog or digital amp meter electrically connected to a current transformer 112 via electrical wiring 114. The current transformer 112 may be disposed about the wire 214 providing current from the power source 212 to the first fan 210. The current transformer 112, for example, a donut current transformer, may be configured to sense the amount of amps running through the wire 214 and generate milliamps that run through the wiring 114 to the first gauge 110. As a result, the monitoring device 100 is electrically isolated from the HVAC system 200, but uses no external power either. Therefore, the monitoring device 100 does not sap power from the HVAC system 200, and, should the monitoring device 100 experience a fault, operation of the HVAC system 200 will not be affected. According to various aspects, the first gauge 110 can output the number of amps running through the wire 214 based on the milliamps generated by the transformer 112.

The second gauge 120 of the monitoring device 100 may be configured to monitor the current being drawn by the second fan 220 in a manner similar to that described in connection with the first fan 210. Alternatively, the second gauge 120 may be configured to monitor any other component of the HVAC system 200.

The third gauge 130 of the monitoring device 100 may be configured to monitor the pressure of refrigerant being discharged from the pump 230. The third gauge 130 may be connected to a first service port 232 associated with the pump 230 via, for example, a capillary tube 132. The capillary tube 132 may be shielded in order to prevent a hole or a leak from occurring.

Similarly, the fourth gauge 140 of the monitoring device 100 may be configured to monitor the pressure of refrigerant being drawn into the pump 230.

The fourth gauge 140 may be connected to a second service port 234 associated with the pump 230 via, for example, a capillary tube 142. The capillary tube 142 may be shielded in order to prevent a hole or a leak from occurring.

The fifth gauge 150 of the monitoring device 100 may be configured to monitor the amps being drawn by the compressor/pump 230. The fifth gauge 150 may be, for example, an analog or digital amp meter electrically connected to a current transformer 152 via electrical wiring 154. The current transformer 152 may be disposed about the wire 254 providing current from the power source 252 to the compressor 230. The current transformer 152, for example, a donut current transformer, may be configured to sense the amps running through the wire 254 and generate milliamps that run through the wiring 154 to the fifth gauge 150. The fifth gauge 150 can output the number of amps running through the wire 254 based on the milliamps generated by the transformer 152.

According to some aspects, the monitoring device 100 may include one or more additional gauges (not shown). The additional gauge(s) may be configured to sense current being drawn by a component, the voltage used by a component, the pressure of a fluid, or the temperature of a component or fluid. Voltage or temperature may be measured by a voltmeter. In the case of temperature, the voltmeter may comprise, for example, a well-mounted thermometer, a strap-on-type thermometer, or the like.

It should be appreciated that the monitoring device 100 can be easily adapted to monitor the current of any wire or appliance desired. The face of the monitoring device 100 can also be easily adapted to accommodate as many gauges of various shapes as desired. As mentioned above, the device 100 can be used to measure current, voltage, pressure, or temperature of any number of components.

It also should be appreciated that the monitoring device 100 may be mounted to the HVAC system 200 or whatever appliance it is monitoring. As a result, it provides a continuous dashboard-type readout of the system 200 that any unskilled person can read without the need for taking the unit apart or calling in a skilled technician. The visual read-out can then be conveyed to a technician in order to determine whether a skilled technician service call is needed.

It will be apparent to those skilled in the art that various modifications and variations can be made to the devices of the disclosure without departing from the scope of the invention. Other embodiments of the invention will be apparent to those skilled in the art from consideration of the specification and practice of the invention disclosed herein. It is intended that the specification and examples be considered as exemplary only.

What is claimed is:

1. An equipment monitoring device for monitoring a heating, ventilation, and air conditioning (HVAC) system configured to control an internal environment of a structure, the device comprising:
a current transformer configured to sense current being supplied from a power source to a first component of the HVAC system; and
a gauge configured to display the amount of current being supplied from the power source to the first component based on the current sensed by the current transformer.

2. The device of claim 1, wherein said gauge is configured to permit monitoring of the HVAC system without disassembling the system.

3. The device of claim 1, wherein said device is isolated from the power source such that the device does not draw power from the power source.

4. The device of claim 1, wherein said first component is one of a fan and a pump.

5. A method for monitoring a heating, ventilation, and air conditioning (HVAC) system configured to control an internal environment of a structure, the method comprising:
monitoring current being supplied from a power source to a first component of the HVAC system without drawing power from the system.

6. The method of claim 4, wherein said monitoring current comprises sensing the current being supplied from the power source to a first component of the HVAC with a current transformer.

7. The method of claim 5, wherein said monitoring current further comprises displaying the amount of current being supplied from the power source to the first component based on the current sensed by the current transformer.

8. An equipment monitoring device for monitoring a heating, ventilation, and air conditioning (HVAC) system configured to control an internal environment of a structure, the device comprising:
a first gauge configured to display current being drawn by a fan employed by the HVAC system;
second gauge configured to display pressure of refrigerant being discharged from a pump employed by the HVAC system;
third gauge configured to display pressure of refrigerant being drawn into the pump; and
a fourth gauge configured to display current being drawn by the pump.

9. The device of claim 8, wherein said fan is inside the structure.

10. The device of claim 8, wherein said fan is outside the structure.

11. The device of claim 8, further comprising a fifth gauge configured to display current being drawn by a second fan employed by the HVAC system, one of said fan and said second fan being inside the structure, and the other of said fan and said second fan being outside the structure.

12. The device of claim 8, further comprising an additional gauge configured to display a temperature of at least one of a component and a fluid of the HVAC system.

13. The device of claim 8, further comprising:
a first current transformer configured to sense current being supplied from a power source to said fan, the first gauge being configured to display the amount of current being supplied from the power source to the fan based on the current sensed by the first current transformer.

14. The device of claim 13, further comprising:
a second current transformer configured to sense current being supplied from the power source to said pump, the fourth gauge being configured to display the amount of current being supplied from the power source to the pump based on the current sensed by the second current transformer.

15. The device of claim 8, further comprising:
a current transformer configured to sense current being supplied from a power source to said pump, the fourth gauge being configured to display the amount of current being supplied from the power source to the pump based on the current sensed by the current transformer.

16. The device of claim 8, wherein said gauges are configured to permit monitoring of the HVAC system without disassembling the system.

17. The device of claim 8, wherein said device is isolated from every power source of the system such that the device does not draw power from said power source.
